(19) United States
(12) Patent Application Publication
(10) Pub. No.: US 2012/0255612 A1
(43) Pub. Date: Oct. 11, 2012

(54) ALD OF METAL OXIDE FILM USING PRECURSOR PAIRS WITH DIFFERENT OXIDANTS

(76) Inventor: Dieter Pierreux, Almere (NL)

(21) Appl. No.: 13/082,658

(22) Filed: Apr. 8, 2011

(51) Int. Cl. H01L 31/0264; H01L 21/31; H01L 31/036; H01L 31/0368

(52) U.S. Cl. 136/261; 438/97; 438/761; 257/E31.043; 257/E31.04; 257/E21.24

(57) ABSTRACT

Discloses is a method for depositing a thin metal oxide film on a substrate, comprising: providing a substrate (104); sequentially and alternatingly exposing a surface of said substrate to a first metal precursor and a first oxidant precursor, so as to deposit a first portion (116) of said metal oxide film (114) having a first thickness; and sequentially and alternatingly exposing the surface of the substrate to a second metal precursor and a second oxidant precursor, so as to deposit a second portion (118) of said metal oxide film (114) having a second thickness over said first portion of said metal oxide film, wherein the second oxidant precursor is ozone or oxygen plasma, while the first oxidant precursor is a milder oxidant than ozone. Also disclosed is a solar cell (100) including a metal oxide passivation film (114) deposited by said method.

### FIELD OF THE INVENTION

The present invention relates to the field of semiconductor processing, and more in particular to a method for the deposition of a thin metal oxide film on a semiconductor substrate, such as an aluminum oxide passivation film on a silicon solar cell.

### BACKGROUND

The use of gaseous ozone or an oxygen plasma in atomic layer deposition (ALD) processes, for instance for the deposition of metal oxide and silicon oxide films, is known in the art. Where ozone or an oxygen plasma is used as a precursor, it has typically been selected for its powerful oxidizing qualities.

In some applications the use of ozone or oxygen plasma instead of milder oxidant precursors, such as water, may allow ALD to be carried out at a relatively low process temperature. See for example U.S. Pat. No. 7,771,533 (Tois et al.), which for this reason teaches the deposition of thin silicon dioxide films through ALD with ozone as a preferred oxidant precursor. Another known advantage of using ozone or oxygen plasma instead of less aggressive oxidants is that fewer impurities are incorporated in the deposited film, which results in a generally better film quality. A notorious downside of ozone and oxygen plasma, however, is that they may attack the underlying substrate. That is, they may undesirably oxidize the original substrate, e.g. a silicon wafer, or materials already deposited thereon, e.g. thin films that contain oxidizable material such as metal. The unintentional oxidation of the substrate may cause damage thereto and result in poor interface properties.

One example of the disadvantageous effect of ozone as a precursor is the deposition of an aluminum oxide (Al₂O₃) passivation film on a silicon solar cell. Relative to a passivation film deposited with water as the oxidant precursor, the use of ozone is observed to result in a relatively high interface state density and a correspondingly low quality surface passivation. The poor surface passivation quality manifests itself in a relatively small lifetime of minority charge carriers, and thus in a low efficiency of the solar cell. Accordingly, water may be the preferred oxidant precursor when depositing an aluminum oxide passivation film, despite some of the advantageous properties of ozone.

### SUMMARY OF THE INVENTION

It is an object of the present invention to enable the atomic layer deposition of a metal oxide film on a substrate in such a way that the film exhibits the advantageous effects of the use of ozone or oxygen plasma as the oxidant precursor during deposition, while the disadvantageous effects of such use are mitigated.

It is another object of the present invention to enable the deposition of an aluminum oxide passivation film on a silicon solar cell substrate, wherein the passivation film has improved characteristics relative to those of conventional ALD deposited aluminum oxide passivation films.

It is a further object of the present invention to provide for a solar cell with an improved efficiency, in particular as a result of the application of the aforementioned passivation film with improved characteristics.

A first aspect of the present invention is therefore directed to a method for depositing a thin metal oxide film on a substrate. The method includes providing a substrate. The method also includes sequentially and alternatingly exposing a surface of said substrate to a first metal precursor and a first oxidant precursor, so as to deposit a first portion of said metal oxide film having a first thickness. The method further includes sequentially and alternatingly exposing the surface of the substrate to a second metal precursor and a second oxidant precursor, so as to deposit a second portion of said metal oxide film having a second thickness over said first portion of said metal oxide film. In this method the second oxidant precursor is gaseous ozone or an oxygen plasma, while the first oxidant precursor is an other, preferably milder, oxidant than gaseous ozone or oxygen plasma.

A metal oxide film (of one and the same metal oxide) is thus deposited using two different precursor or reactant pairs, each comprising a metal precursor and an oxidant precursor. The first and second portions of the film have different characteristics as a result of the different oxidant precursors used to deposit them. The first precursor pair may generally be chosen to optimize the properties of the substrate/film interface, such as the interface state density, while the second precursor pair including gaseous ozone or oxygen plasma may be used to optimize the bulk properties of the film, e.g. the fixed charge density thereof, and/or the conditions of the deposition process.

A second aspect of the present invention is directed to a solar cell that includes a metal oxide film deposited by means of the method according to the first aspect of the invention. The solar cell may include a mono-, poly- or multi-crystalline silicon substrate, while the metal oxide film may be an aluminum oxide (Al₂O₃) surface passivation film that has been deposited thereon, for example using trimethylaluminum/water and trimethyl-aluminum/(ozone or oxygen plasma) precursor pairs.

These and other features and advantages of the invention will be more fully understood from the following detailed description of certain embodiments of the invention, taken together with the accompanying drawings, which are meant to illustrate and not to limit the invention.

### BRIEF DESCRIPTION OF THE DRAWINGS

FIG. 1 is a schematic cross-sectional side view of an exemplary solar cell according to the present invention on which sunlight is incident; and

FIG. 2 is a schematic cross-sectional side view of transistor gate stack formed on top of a silicon substrate;

### DETAILED DESCRIPTION

Atomic layer deposition (ALD) is a thin film deposition method wherein two or more gaseous precursors are alternately and repeatedly applied to a substrate. A series of sequential steps in which a surface of the substrate is exposed to all precursors is called a deposition cycle. Each deposition cycle grows a single monolayer of the desired film. This is due to the fact that in ALD the film growth depends on chemisorption, a process whereby a precursor molecule adheres to a substrate's surface through the formation of a chemical bond without further thermal decomposition of the precursor molecule taking place. Chemisorption stops naturally when all substrate surface sites available for chemical bonding with a precursor have been covered. Hence, exposing a substrate to a first precursor results in a first-precursor-monolayer that is one atom or molecule thick on the entire exposed substrate surface; i.e. a saturated monolayer. Practically, chemisorption may not occur on all portions of the exposed surface, for example due to steric hindrance. Nevertheless, such an imperfect monolayer is still regarded as a monolayer in the context of this disclosure. Subsequently exposing the substrate to the second precursor results in a chemical reaction of the second precursor with the chemisorbed first precursor under the formation of a solid monolayer of the desired film, until all of the chemisorbed first precursor has been reacted and the substrate is covered with chemisorbed second precursor in a self-limiting manner. Consequently, ALD is a deposition method that enables highly conformal coating by high quality layers. These characteristics make it a method of interest to various industries, among which in particular the semiconductor industry, including the solar cell industry.

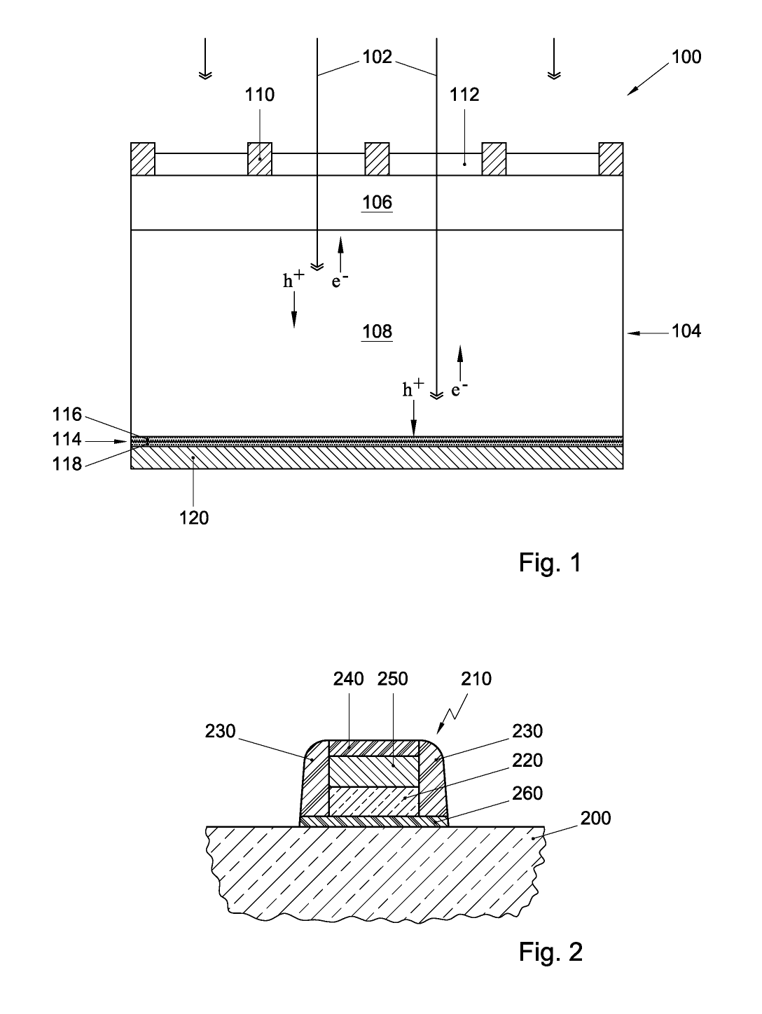

A first exemplary ALD application is the deposition of passivation films on the rear surface of a solar cell. FIG. 1 is a schematic cross-sectional side view of an exemplary solar cell 100 that features such a passivation film 114. The solar cell 100 comprises a crystalline silicon body 104. Electrical current generated in the body 104 is extracted via electrical contacts 110, 120 at the front and the rear of the cell 100. The front contact structure is made in the form of a widely spaced metal grid 110 that allows light 102 to pass through. Within the openings of the grid 110 the front surface of the cell 100 is provided with an anti-reflection coating 112 to minimize light reflection. At the rear surface, the silicon body 104 is provided with the aluminum oxide (Al₂O₃) passivation film 114 whose primary function is to prevent the undesired recombination of generated minority charge carriers at the back surface. On top of the passivation film 114 a full area metal back contact 120 is provided. Through proper doping, the silicon body 104 is divided between an n-type region 106 and a p-type region 108, so as to provide for a p-n junction near the light receiving surface of the solar cell 100. During operation, light incident on the cell 100 generates electron (e⁻)-hole (h⁺) pairs on both sides of the p-n junction, i.e. both in the n-type emitter 106 and in the p-type base 108. Electrons generated in the base 108 diffuse across the p-n junction towards the emitter 106, while holes generated in the emitter 106 diffuse across the junction towards the base 108, thus producing an electric voltage across the cell 100.

The quality of the passivation film 114 determines to a significant extent the effective minority charge carrier lifetime of the cell 100, and thus the capability of current production thereof. To optimize the minority charge carrier lifetime, the passivation film 114 may preferably have a low interface state density at the substrate/passivation film interface. A lower interface state density translates into a longer lifetime of the minority charge carriers in the substrate and, hence, in a higher efficiency of the solar cell. Another important parameter of a passivation film is the fixed (here: negative) charge density located at or near the substrate/passivation film interface. Fixed charges incorporated in the passivation film 114 produce effective field-effect passivation, which improves the minority carrier lifetime further.

For solar cell applications, aluminum oxide (Al₂O₃) films have proven to provide for good passivation of the surface of silicon substrates. An aluminum oxide film may conventionally be deposited through ALD using a single precursor pair including trimethylaluminum (TMA) and water (H₂O) as the metal and oxidant precursors, respectively. A passivation film deposited using the TMA/H₂O precursor pair may typically result in a film having a relatively low interface state density of about 2-3×10¹¹/eVcm², and a relatively low fixed negative charge density of about 10¹¹cm⁻². Hence, the level of chemical surface passivation of the silicon substrate surface is satisfactory, while the additional field-effect passivation leaves to be desired.

Interestingly, it has been found that an aluminum oxide film deposited through ALD using an alternative precursor pair including TMA and ozone (O₃) has reversed qualitative characteristics. Such a film may typically exhibit a relatively high interface state density of about 5×10¹² to 10¹³/eVcm², and a relatively high fixed negative charge density of about 6×10¹²cm⁻².

The above differences in characteristics can be exploited to optimize the characteristics of an aluminum oxide passivation film 114, namely by depositing the first portion 116 of the film using a precursor pair including TMA and water to achieve optimum surface passivation, and depositing a second portion 118 with the alternative precursor pair including TMA and ozone to achieve the additional benefit of field-effect passivation.

In an experimental and exemplary embodiment of the method according to the present invention, an aluminum oxide film was deposited as a passivation film for photovoltaic applications. A plurality of silicon substrates was loaded into an A412™ vertical furnace of ASM International, Almere, The Netherlands. The substrates were first exposed to alternating and sequential pulses of TMA and water until a first portion of the aluminum oxide film having a first film thickness of 2 nm had been deposited. Subsequently, the substrates were exposed to alternating and sequential pulses of TMA and ozone until a second portion of the aluminum oxide film having a second film thickness of 28 nm had been grown. The overall film thickness of the deposited aluminum oxide film thus amounted to 30 nm.

A second exemplary application of the present invention is the formation of a high-x metal oxide gate dielectric layer in a transistor structure, such as that described in U.S. Pat. No. 7,026,219, which is hereby incorporated by reference. FIG. 2, which corresponds to FIG. 7 of US'219,illustrates a semiconductor substrate 200 on which a transistor gate stack 210, incorporating a high-x dielectric layer 260, has been formed.

The substrate 200 includes an upper portion of a single-crystal silicon wafer, though the skilled artisan will appreciate that the substrate may also comprise other semiconductor materials. The gate stack 210 includes a polysilicon or poly-SiGe gate electrode layer 220. Sidewall spacers 230 and an insulating layer 240 protect and isolate the electrode layer 220 in a conventional manner. Also illustrated is a highly conductive strapping layer 250, typically including metal, disposed over the silicon-containing gate electrode layer 220. The strapping layer 250 facilitates rapid signal propagation among transistor gates across the substrate 200, connecting the gates to logic circuits. A high-κ metal oxide gate dielectric 260, formed by an embodiment of the invention, separates the gate electrode 220 from the substrate 200. The gate dielectric 260 is a critical feature in the pursuit of denser and faster circuits. Exposure of the substrate 200 to ozone or an oxygen plasma results in oxidation of the substrate and formation of a silicon oxide layer. The Effective Oxide

Thickness (EOT) of the silicon oxide layer will be significant in comparison to the EOT of the high-x of the gate dielectric layer 260, and increases the EOT of the combination silicon oxide/gate dielectric layer 260, disposed between substrate 200 and gate electrode 220 to unacceptably high levels. On the other hand, the use of an aggressive oxidant like ozone or oxygen plasma results in a high quality high-x gate dielectric 260. Depositing an initial portion of the high-x dielectric layer 260 using an oxidant milder than ozone or oxygen plasma thus avoids oxidation of the substrate. A subsequent portion of the high-κ dielectric layer 260 may then be deposited using ozone or oxygen plasma while the substrate 200 is protected against oxidation by the initial portion of the high-κ dielectric layer 260. In this way the benefits of the use of ozone or oxygen plasma can be exploited while avoiding the disadvantages. Suitable metal oxides for a high-κ dielectric layer include aluminum oxide (Al₂O₃), zirconium oxide (ZrO₂), hafnium oxide (HfO₂), tantalum oxide (Ta₂O₅), barium strontium titanate (BST), strontium bismuth tantalate (SBT), and lanthanide oxides. The last listed dielectrics include oxides of such physically stable “rare earth” elements as scandium (Sc), yttrium (Y), lanthanum (La), cerium Ce, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu).

A third general exemplary application of the method according to the present invention is the deposition of a metal oxide layer over a substrate comprising exposed metal portions. The metal oxide layer may for instance serve to prevent corrosion of the metal, or to form an electrically insulative layer between the yet exposed metal portions and a new metal layer to be deposited on top thereof. Cases of such deposition of a metal oxide layer may commonly be found in semiconductor technology, flat panel display technology, sensor technology, LEDs etc.

A specific example is the production of a high brightness LED, which may involve a substrate comprising one or more silver layers, used for contacting the active areas of the LEDs. A dielectric metal oxide layer, e.g. an aluminum oxide layer, may be deposited onto the silver layers as a protective, corrosion preventing layer. Alternatively, a metal oxide layer may be used as a dielectric isolation layer between subsequent metallization layers. As exposing the silver layers to ozone or oxygen plasma would cause the undesirable oxidation of the silver, it may be preferred to deposit a first portion of the layer by means of a precursor pair comprising TMA and water (thus preventing silver oxidation), and a second portion of the layer using TMA and ozone (to optimize quality of the bulk of the layer and the conditions its deposition process).

It is noted that the use of ozone as a ALD precursor, as envisaged by the present invention, should be distinguished from the use of ozone as a process gas in discrete intermediate steps in an ALD process. An example of such use is given by U.S. Pat. No. 6,124,158 (Dautartas et al), which teaches the periodical exposure of a substrate to ozone in between completed deposition cycles. The periodic exposure to ozone serves to oxidize carbon contaminants, so as to form gaseous products therewith. The gaseous products can then be purged from the reaction chamber using an inert gas, which avoid the adverse incorporation of the contaminants into the film that is being deposited. Although the discrete ozone treatment step suggested by US'158 may improve the quality of a film that is being deposited using organic sources, the separate exposure and purging steps necessarily complicate and prolong the deposition process. In addition, the final film is still of a lesser quality than a similar film deposited using an ozone precursor.

Generalizing the above-described exemplary embodiments and applications of the method according to the present invention, it is contemplated that the first oxidant precursor may be selected from the group consisting of water (H₂O), non-plasmatic (e.g. gaseous) oxygen (O₂), oxides of nitrogen (NₓO_{y}) and alcohols (CₓH_{y}(OH)_{z}); the first oxidant may preferably be water.

The first and second metal precursors may be selected from the groups of metal halide precursors and metal organic precursors. The metal organic precursor may, for example, be a metal alkyl precursor or a metal amino precursor. The first and second metal precursors may be different compounds, as long as they provide for the same metal. Alternatively, the first and second metal precursors may be the same. It is contemplated that the first and second metal precursors may include and form a source material for a metal from the groups of: Be, Mg, Sr, Ba, Ra (group 2: alkaline earth metals); Sc, Y, La, Ac/Ti, Zr, Hf/V, Nb, Ta/Cr, Mo, W/Mn, Tc, Re (groups 3-7: transition metals); Zn/Al, Ga, In, Tl/Si, Ge, Sn, Pb (group 12-14: metals).

Where the method according to the present invention is applied to deposit a passivation film for a solar cell, the substrate may preferably be a mono-, poly-, or multi-crystalline silicon substrate. The thickness of the first (interface) portion of the passivation film may preferably be in the range of 0.5-5 nm, and more preferably 0.5-2 nm, while the thickness of the second (bulk) portion of the film may preferably be in the range of 5-100 nm, and more preferably 20-40 nm.

It is understood that the atomic layer deposition of a metal oxide film according to the present invention may be carried out using any suitable type of equipment. This includes the aforementioned vertical batch-type reactors marketed by ASM International, Almere, The Netherlands, in which the substrate is exposed to temporal pulses of precursors, and in-line ALD-reactors as disclosed in for example patent application WO 2009/142488 and marketed by Levitech, Almere, The Netherlands, in which floatingly supported substrates travel through spatially separated precursor comprising zones.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims. Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

### LIST OF ELEMENTS

100 solar cell
102 sun light
104 silicon body
106 n-type layer
108 p-type layer
110 metal grid
112 anti-reflection coating
114 passivation film
116 first portion of passivation film
118 second portion of passivation film
120 metal back contact
200 semiconductor substrate
210 transistor gate stack
220 gate electrode layer
230 sidewall spacer
240 insulating layer
250 strapping layer
260 metal oxide gate dielectric

1. A method for depositing a thin metal oxide film on a substrate, comprising:
providing a substrate;
sequentially and alternatingly exposing a surface of said substrate to a first metal precursor and a first oxidant precursor, so as to deposit a first portion of said metal oxide film having a first thickness; and
sequentially and alternatingly exposing the surface of the substrate to a second metal precursor and a second oxidant precursor, so as to deposit a second portion of said metal oxide film having a second thickness over said first portion of said metal oxide film,
wherein the second oxidant precursor is oxygen plasma or ozone, while the first oxidant precursor is a milder oxidant than oxygen plasma or ozone.

2. The method according to claim 1, wherein the first oxidant is selected from the group comprising: water, non-plasmatic oxygen, oxides of nitrogen, and alcohols.

3. The method according to claim 1, wherein at least one of the first and second metal precursor is a metal organic precursor or a metal halide precursor.

4. The method according to claim 3, wherein the first precursor is an aluminum precursor, for example trimethylaluminum (TMA).

5. The method according to claim 1, wherein the first and second metal precursors are the same.

6. The method according to claim 1, wherein the substrate is mono-, poly-, or multi-crystalline silicon substrate, suitable for manufacturing a solar cell.

7. The method according to claim 1, wherein the metal oxide film is a passivation layer in a solar cell, and the first thickness is in the range of 0.5-5 nm, and preferably 0.5-2 nm.

8. The method according to claim 1, wherein the metal oxide film is a passivation layer in a solar cell, and the second thickness is in the range of 5-100 nm, and preferably 20-40 nm.

9. The method according to claim 1, wherein the metal oxide film is a high-κ dielectric layer in a gate stack.

10. A solar cell including a metal oxide film deposited by means of the method according to claim 1.

11. The solar cell according to claim 10, wherein the solar cell includes a silicon substrate and wherein the metal oxide film is an aluminum oxide (Al203) passivation film deposited thereon.

12. A solar cell including a metal oxide film deposited by means of the method according to claim 2.

13. A solar cell including a metal oxide film deposited by means of the method according to claim 3.

14. A solar cell including a metal oxide film deposited by means of the method according to claim 4.

15. A solar cell including a metal oxide film deposited by means of the method according to claim 5.

16. A solar cell including a metal oxide film deposited by means of the method according to claim 6.

17. A solar cell including a metal oxide film deposited by means of the method according to claim 7.

18. A solar cell including a metal oxide film deposited by means of the method according to claim 8.

19. A solar cell including a metal oxide film deposited by means of the method according to claim 9.

20. The solar cell according to claim 12, wherein the solar cell includes a silicon substrate and wherein the metal oxide film is an aluminum oxide (Al2O3) passivation film deposited thereon.

21. The solar cell according to claim 13, wherein the solar cell includes a silicon substrate and wherein the metal oxide film is an aluminum oxide (Al2O3) passivation film deposited thereon.

22. The solar cell according to claim 14, wherein the solar cell includes a silicon substrate and wherein the metal oxide film is an aluminum oxide (Al203) passivation film deposited thereon.

23. The solar cell according to claim 15, wherein the solar cell includes a silicon substrate and wherein the metal oxide film is an aluminum oxide (Al2O3) passivation film deposited thereon.

24. The solar cell according to claim 16, wherein the solar cell includes a silicon substrate and wherein the metal oxide film is an aluminum oxide (Al2O3) passivation film deposited thereon.

25. The solar cell according to claim 17, wherein the solar cell includes a silicon substrate and wherein the metal oxide film is an aluminum oxide (Al2O3) passivation film deposited thereon.

26. The solar cell according to claim 18, wherein the solar cell includes a silicon substrate and wherein the metal oxide film is an aluminum oxide (Al2O3) passivation film deposited thereon.

27. The solar cell according to claim 19, wherein the solar cell includes a silicon substrate and wherein the metal oxide film is an aluminum oxide (Al2O3) passivation film deposited thereon.
